(19) United States
(12) Patent Application Publication
(10) Pub. No.: US 2025/0062593 A1
(43) Pub. Date: Feb. 20, 2025

(54) SEMICONDUCTOR LASER ELEMENT

(71) Applicant: Panasonic Holdings Corporation, Osaka (JP)

(72) Inventor: HIROYUKI HAGINO, Osaka (JP)

(21) Appl. No.: 18/937,104

(22) Filed: Nov. 5, 2024

Related U.S. Application Data
(63) Continuation of application No. PCT/JP2023/012212, filed on Mar. 27, 2023.

(30) Foreign Application Priority Data
May 19, 2022 (JP) 2022-082136

(51) Int. Cl. H01S 5/065; H01S 5/20

(52) U.S. Cl. CPC H01S 5/0655; H01S 5/2018

(57) ABSTRACT

A semiconductor laser element includes a light emitting layer, a transparent electrode, and a p-side semiconductor layer disposed between the light emitting layer and the transparent electrode in a first direction. The p-side semiconductor layer includes a flat portion and a protruding portion protruding from the flat portion toward the transparent electrode, the protruding portion extending in a second direction orthogonal to the first direction, the transparent electrode extends in the second direction, and orthogonal projection of the transparent electrode onto the light emitting layer is included in orthogonal projection of the protruding portion onto the light emitting layer.

### TECHNICAL FIELD

The present disclosure relates to a semiconductor laser element.

### BACKGROUND ART

In recent years, semiconductor laser elements have attracted attention as light sources available for various applications. Examples of the various applications include a light source for an image display such as a display or a projector, a light source for an in-vehicle headlamp, a light source for industrial illumination, a light source for consumer illumination, or a light source for industrial equipment such as a laser welding device, a thin film annealing device, or a laser processing device.

The semiconductor laser elements used for such applications are required to have high power exceeding 1 W and high beam quality.

A laser beam emitted by the semiconductor laser element includes light in a basic mode in a lateral direction (hereinafter, simply referred to as a “basic mode”.) and light in a higher-order mode in the lateral direction (hereinafter, simply referred to as a “higher-order mode”.). In order to realize high beam quality, the semiconductor laser element desirably performs laser oscillation in the basic mode, and for this purpose, it is necessary to perform laser oscillation in a state where there is no higher-order mode (so-called cut-off state).

In order to suppress the higher-order mode, there is a method for narrowing a width of a waveguide. However, in order to realize high power, a waveguide having a narrow width is disadvantageous, and a waveguide having a wide width (so-called wide stripe) is advantageous. Thus, the high-power laser beam exceeding 1 W has a high proportion of higher-order modes.

Accordingly, in order to realize the laser beam with high power and high beam quality, it is necessary to reduce the proportion of the higher-order modes in the high-power laser beam.

PTL 1 discloses a semiconductor laser element formed such that a width of a waveguide increases or decreases in a resonator length direction. In this laser element, the higher-order mode is suppressed by increasing or decreasing the width of the waveguide.

### CITATION LIST

### Patent Literature

PTL 1: Unexamined Japanese Patent Publication No. H09-246664

### SUMMARY OF THE INVENTION

A semiconductor laser element according to an aspect of the present disclosure includes a light emitting layer, a transparent electrode, and a p-side semiconductor layer disposed between the light emitting layer and the transparent electrode in a first direction. The p-side semiconductor layer includes a flat portion and a protruding portion protruding from the flat portion toward the transparent electrode, the protruding portion extending in a second direction orthogonal to the first direction, the transparent electrode extends in the second direction, and orthogonal projection of the transparent electrode onto the light emitting layer is included in orthogonal projection of the protruding portion onto the light emitting layer.

### BRIEF DESCRIPTION OF THE DRAWINGS

FIG. 1 is a plan view of a semiconductor laser element according to an exemplary embodiment.

FIG. 2 is a sectional view taken along line II-II in FIG. 1.

FIG. 3 is a sectional view illustrating a manufacturing step of the semiconductor laser element.

FIG. 4 is a sectional view illustrating the manufacturing step of the semiconductor laser element.

FIG. 5 is a sectional view illustrating the manufacturing step of the semiconductor laser element.

FIG. 6 is a sectional view illustrating the manufacturing step of the semiconductor laser element.

FIG. 7 is a sectional view illustrating the manufacturing step of the semiconductor laser element.

FIG. 8 is a sectional view illustrating the manufacturing step of the semiconductor laser element.

FIG. 9 is a sectional view illustrating the manufacturing step of the semiconductor laser element.

FIG. 10 is a sectional view illustrating the manufacturing step of the semiconductor laser element.

FIG. 11 is a sectional view illustrating the manufacturing step of the semiconductor laser element.

FIG. 12 is a sectional view illustrating the manufacturing step of the semiconductor laser element.

FIG. 13 is a sectional view illustrating the manufacturing step of the semiconductor laser element.

FIG. 14 is a sectional view illustrating the manufacturing step of the semiconductor laser element.

FIG. 15 is a plan view of the semiconductor laser device on which the semiconductor laser element according to the exemplary embodiment is implemented.

FIG. 16 is a sectional view taken along line XVI-XVI in FIG. 15.

FIG. 17 is a partially enlarged view of FIG. 2.

FIG. 18 is a graph representing a calculation result regarding a loss of a laser beam.

FIG. 19 is a graph representing a calculation result regarding beam quality.

FIG. 20 is a plan view of a semiconductor laser element according to Modification 1.

FIG. 21 is a plan view of a semiconductor laser element according to Modification 2.

FIG. 22 is a plan view of a semiconductor laser element according to Modification 3.

### DESCRIPTION OF EMBODIMENT

Not only a higher-order mode but also a basic mode is suppressed by increasing or decreasing a width of a waveguide, and there is a possibility that a proportion of higher-order modes in the entire laser beam is not reduced. That is, a semiconductor laser element of PTL 1 is insufficient in realizing a laser beam with high beam quality.

An object of the present disclosure is to provide a semiconductor laser element capable of emitting a laser beam with high beam quality.

Hereinafter, an exemplary embodiment of the present disclosure will be described with reference to the drawings. The present disclosure will be described by using right-handed orthogonal coordinates. A Y-axis extends in a direction in which a laser beam propagates. A Z-axis extends in a direction in which layers constituting a semiconductor laser element according to the present disclosure overlap each other. A direction from n-side electrode 80 to be described later toward pad electrode 70 is a positive direction of the Z-axis.

### EXEMPLARY EMBODIMENT

### [Configuration of Semiconductor Laser Element]

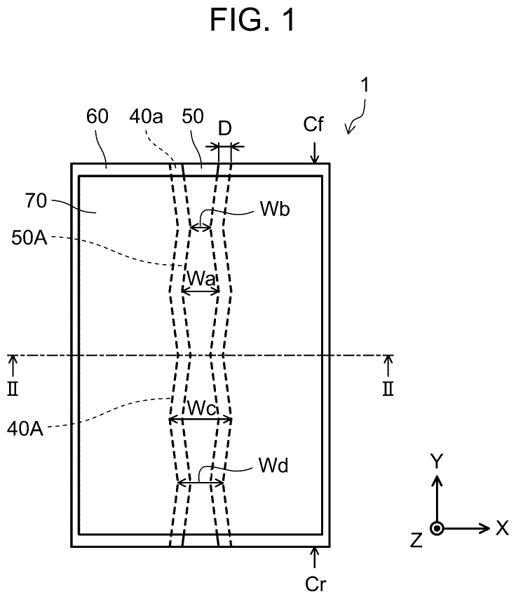

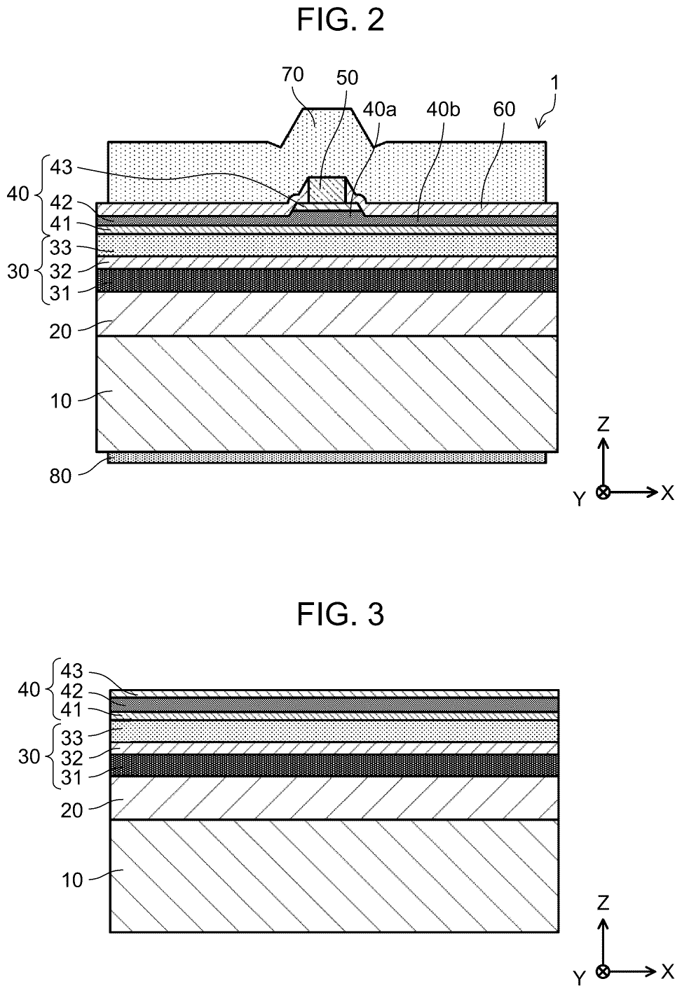

A configuration of semiconductor laser element 1 according to an exemplary embodiment will be described with reference to FIGS. 1 and 2. FIG. 1 is a plan view of semiconductor laser element 1. 40A in FIG. 1 denotes orthogonal projection of protruding portion 40a (to be described later) onto light emitting layer 30 (to be described later). 50A in FIG. 1 denotes orthogonal projection of transparent electrode 50 (to be described later) onto light emitting layer 30. FIG. 2 is a sectional view taken along line II-II in FIG. 1. FIG. 2 is a sectional view of semiconductor laser element 1 taken along an XZ plane.

Semiconductor laser element 1 is, for example, a nitride semiconductor element, and emits a laser beam with a blue wavelength region, that is, relatively high power. Hereinafter, semiconductor laser element 1 according to the present exemplary embodiment will be described as the nitride semiconductor device.

Semiconductor laser element 1 has a resonator structure, and the resonator structure is formed of front end surface Cf and rear end surface Cr. In FIG. 1, since the laser beam emitted inside semiconductor laser element 1 travels back and forth between front end surface Cf and rear end surface Cr in a resonator length direction (Y-axis direction. hereinafter, this direction may be referred to as a second direction in the present specification), the resonator length direction corresponds to a resonance direction of the laser beam. In addition, the laser beam is emitted from front end surface Cf to an outside.

Semiconductor laser element 1 includes substrate 10, n-side semiconductor layer 20, light emitting layer 30, p-side semiconductor layer 40, transparent electrode 50, dielectric layer 60, pad electrode 70, and n-side electrode 80 which are stacked in a Z direction (hereinafter, may be described as a first direction in the present specification).

Substrate 10 is, for example, a GaN substrate. More specifically, substrate 10 is an n-type hexagonal GaN substrate having a (0001) surface as a main surface.

Substrate 10 has a thickness of, for example, 90 μm. Substrate 10 may have a thickness that can be cleaved at the time of dicing, and may have a thickness of, for example, from 50 μm to 130 μm inclusive.

n-side semiconductor layer 20 is a conductive nitride semiconductor layer stacked on substrate 10.

A thickness of n-side semiconductor layer 20 is from 0.5 μm to 5.0 μm inclusive, and is, for example, 3 μm.

n-side semiconductor layer 20 is an n-side cladding layer made of, for example, n-type AlₓGa₁₋ₓN (0<x<1). More specifically, n-side semiconductor layer 20 is an n-side cladding layer made of n-type Al_{0.03}Ga_{0.97}N. Note that, n-side semiconductor layer 20 may be an n-side cladding layer made of a material having a different Al composition ratio (that is, different values of x), that is, a material other than n-type Al_{0.03}Ga_{0.97}N.

Note that, in a case where at least one of the thickness of n-side semiconductor layer 20 and a ratio of Al to Ga is relatively large, a crack is likely to occur due to a lattice constant difference from substrate 10 (here, GaN substrate). In addition, as n-side semiconductor layer 20 becomes thicker, a resistance value for a current flowing between transparent electrode 50 and n-side electrode 80 increases, and a voltage required for laser oscillation may increase.

Light emitting layer 30 is stacked over substrate 10, and has a stacked structure in which n-side light guide layer 31, active layer 32, and p-side light guide layer 33 are stacked in this order.

A thickness of n-side light guide layer 31 is, for example, 0.2 μm. In addition, n-side light guide layer 31 is made of, for example, n-type GaN.

Active layer 32 includes a quantum well layer and a barrier layer, and the quantum well layer is formed between barrier layers. Note that, active layer 32 may have only one quantum well layer or two or more quantum well layers.

A thickness of the quantum well layer is, for example, 5 nm. The quantum well layer is made of, for example, In_{0.06}Ga_{0.94}N. A thickness of the barrier layer is, for example, about 10 nm. The barrier layer is made of, for example, In_{0.02}Ga_{0.98}N.

Note that, the thickness and In composition of the quantum well layer and the thickness and In composition of the barrier layer may be set to be able to emit a laser beam of from about 400 nm to about 470 nm inclusive, and are not necessarily limited to the above-described thickness and In composition.

A thickness of p-side light guide layer 33 is, for example, 0.1 μm. p-side light guide layer 33 is made of, for example, p-type GaN.

p-side semiconductor layer 40 is a conductive nitride semiconductor layer disposed between light emitting layer 30 and transparent electrode 50. In a case where n-side semiconductor layer 20 is of n-type conductivity, p-side semiconductor layer 40 is of p-type conductivity, and in a case where n-side semiconductor layer 20 is of p-type conductivity, p-side semiconductor layer 40 is of n-type conductivity.

p-side semiconductor layer 40 has a stacked structure in which electron barrier layer 41, p-side cladding layer 42, and p-side contact layer 43 are stacked. p-side semiconductor layer 40 has protruding portion 40a and flat portion 40b. Protruding portion 40a is a portion protruding from flat portion 40b toward transparent electrode 50.

A thickness of electron barrier layer 41 is, for example, 10 nm. Electron barrier layer 41 is made of, for example, Al_{0.35}Ga_{0.65}N. Electron barrier layer 41 has a flat shape as a whole and constitutes a part of flat portion 40b.

p-side cladding layer 42 has a flat plate-shaped portion and a ridge-shaped portion protruding from the flat plate-shaped portion. The flat plate-shaped portion of p-side cladding layer 42 constitutes flat portion 40b together with electron barrier layer 41. The ridge-shaped portion of p-side cladding layer 42 protrudes from flat portion 40b toward transparent electrode 50 and extends in the Y-axis direction. The ridge-shaped portion of p-side cladding layer 42 and a portion that is a part of the flat plate-shaped portion and is adjacent to the ridge-shaped portion in a Z-axis direction constitute a waveguide portion through which the laser beam emitted from light emitting layer 30 propagates. Note that, the waveguide portion may be constituted by the ridge-shaped portion of p-side cladding layer 42, a portion that is a part of the flat plate-shaped portion and is adjacent to the ridge-shaped portion in the Z-axis direction, and p-side contact layer 43.

A thickness of p-side cladding layer 42 (here, a thickness of the flat plate-shaped constituting flat portion 40b) is, for example, 0.66 μm. p-side cladding layer 42 includes, for example, a strained superlattice formed by repeatedly stacking a set of a p-type Al_{0.06}Ga_{0.94}N layer and a p-type GaN layer at a predetermined period. Thicknesses of the p-type Al_{0.06}Ga_{0.94}N layer and the p-type GaN layer are, for example, 1.5 nm.

The thickness of p-side cladding layer 42 may be from 0.3 μm to 1 μm inclusive. In addition, p-side cladding layer 42 may have a p-type AlₓGa₁₋ₓN (0<x<1) layer, and may not necessarily have a p-type Al_{0.06}Ga_{0.94}N layer.

p-side contact layer 43 is formed to cover the entire upper surface of the ridge-shaped portion of p-side cladding layer 42. A thickness of p-side contact layer 43 is, for example, about 0.05 μm. p-side contact layer 43 is made of p-type GaN. Note that, in FIG. 2, p-side contact layer 43 is drawn to be relatively thick for easy understanding, but actually, the thickness of p-side contact layer 43 is sufficiently small as compared with the thickness of the ridge-shaped portion of p-side cladding layer 42, and may be ignored.

The ridge-shaped portion of p-side cladding layer 42 and p-side contact layer 43 constitute protruding portion 40a. Protruding portion 40a extends in the Y-axis direction (second direction). Although details will be described later, as can be understood from the shape of orthogonal projection 40A illustrated in FIG. 1, protruding portion 40a has a shape whose width increases or decreases along the Y-axis direction. That is, the protruding portion has a first portion and a second portion adjacent to the first portion in the second direction, the first portion having a width which increases along the second direction, the second portion having a width which decreases along the second direction.

Transparent electrode 50 is an ohmic electrode in ohmic contact with an upper surface of p-side contact layer 43. Transparent electrode 50 is made of a transparent conductive oxide material in ohmic contact with p-side contact layer 43, such as ITO, In₂O₃, or ZnO. In the present exemplary embodiment, transparent electrode 50 is made of ITO.

Transparent electrode 50 is formed in a partial region of the upper surface of p-side contact layer 43. Although details will be described later, transparent electrode 50 extends in the Y-axis direction (that is, second direction), and has a shape whose width increases or decreases along the Y-axis direction.

Dielectric layer 60 is an insulating layer covering p-side semiconductor layer 40. More specifically, dielectric layer 60 is continuously formed from side surfaces of protruding portion 40a and transparent electrode 50 to flat portion 40b, and covers the side surfaces of protruding portion 40a and transparent electrode 50. Thus, dielectric layer 60 functions as a layer that confines light in protruding portion 40a and transparent electrode 50.

For example, as illustrated in FIG. 2, dielectric layer 60 may be in direct contact with the side surface of transparent electrode 50, the side surface of protruding portion 40a, and flat portion 40b. As a result, the laser beam emitted immediately below protruding portion 40a in light emitting layer 30 can be stably confined in the waveguide portion and transparent electrode 50. In this case, a shape of dielectric layer 60 may have a shape in which widths of portions adjacent to protruding portion 40a and transparent electrode 50 increase or decrease in the Y-axis direction in accordance with shapes of transparent electrode 50 and protruding portion 40a.

A thickness of dielectric layer 60 is more than or 100 nm, and is 300 nm in the present exemplary embodiment. In addition, the thickness of dielectric layer 60 may be, for example, less than or equal to a thickness of the waveguide portion (that is, the sum of the thickness of the ridge-shaped portion and the thickness of the flat plate-shaped of p-side cladding layer 42), or may be less than or equal to the thickness of transparent electrode 50. Dielectric layer 60 is made of a low refractive index material having a refractive index lower than a refractive index of a material constituting transparent electrode 50 and a material constituting the waveguide portion. The low refractive index material is, for example, SiO₂.

Note that, in a case where semiconductor laser element 1 emits a high-power laser beam as in the present exemplary embodiment, an end surface coating film is formed on front end surface Cf. The end surface coating film is, for example, a dielectric multilayer film.

Pad electrode 70 is formed to be wider than transparent electrode 50 and covers transparent electrode 50 and dielectric layer 60. Pad electrode 70 is in direct contact with transparent electrode 50 and dielectric layer 60.

Pad electrode 70 is disposed such that the orthogonal projection onto p-side semiconductor layer 40 falls within an upper surface of p-side semiconductor layer 40. That is, pad electrode 70 is not disposed on a peripheral portion of semiconductor laser element 1 in plan view. As a result, when semiconductor laser element 1 is diced, a yield rate can be improved. When a voltage is applied to semiconductor laser element 1, a region (so-called non-current injection region) to which a current is not supplied is formed in the peripheral portion of semiconductor laser element 1.

Pad electrode 70 is made of, for example, a metal material such as Ti, Ni, Pt, or Au. In the present exemplary embodiment, pad electrode 70 has a three-layer structure including, for example, a Ti layer, a Pt layer, and an Au layer.

n-side electrode 80 is an ohmic electrode disposed on a back surface of substrate 10 and in ohmic contact with substrate 10. n-side electrode 80 has, for example, a stacked structure including a Ti layer, a Pt layer, and an Au layer. In addition, n-side electrode 80 may have a stacked structure in which a Ti layer and an Au layer are stacked.

### [Protruding Portion and Transparent Electrode]

Hereinafter, configurations of protruding portion 40a and transparent electrode 50 will be described in detail with reference to FIGS. 1 and 2. D in FIG. 1 is a distance between an outer edge of transparent electrode 50 and an outer edge of protruding portion 40a in an X-axis direction.

In the present exemplary embodiment, transparent electrode 50 is disposed on protruding portion 40a such that orthogonal projection 50A of transparent electrode 50 onto light emitting layer 30 is included in orthogonal projection 40A of protruding portion 40a onto light emitting layer 30. More specifically, a width of transparent electrode 50 is less than a width of protruding portion 40a at any position in the Y-axis direction.

Protruding portion 40a has a shape in which the width of protruding portion 40a periodically increases or decreases along the Y-axis direction. In addition, transparent electrode 50 has a shape in which the width of transparent electrode 50 periodically increases or decreases along the Y-axis direction. Specifically, the side surfaces of protruding portion 40a and transparent electrode 50 have, in plan view, a zigzag shape in which protrusions protruding to a positive side in the X-axis direction and recesses recessed to a negative side are continuous, and a zigzag shape in which protrusions protruding to the negative side in the X-axis direction and recesses recessed to the positive side are continuous. In addition, as illustrated in FIG. 1, the widths of protruding portion 40a and transparent electrode 50 continuously change such that protrusion apexes and recess groove bottoms are linearly connected.

Further, in the present exemplary embodiment, distance D is more than 0 over the entire region along the Y-axis direction (second direction) in which protruding portion 40a and transparent electrode 50 extend.

In transparent electrode 50, a distance between the apexes of the protrusion in the X-axis direction corresponds to maximum width Wa of transparent electrode 50, and a distance between the groove bottoms of the recess in the X-axis direction corresponds to minimum width Wb of the width of transparent electrode 50.

In addition, in protruding portion 40a, the distance between the apexes of the protrusion in the X-axis direction corresponds to maximum width Wc of protruding portion 40a, and the distance between the groove bottoms of the recess in the X-axis direction corresponds to minimum width Wd of protruding portion 40a.

In the present exemplary embodiment, maximum width Wa and minimum width Wb of transparent electrode 50, and maximum width Wc and minimum width Wd of protruding portion 40a are set to be from 1 μm to 100 μm inclusive.

For example, maximum width Wa of transparent electrode 50 may be set to be from 8 μm to 50 μm inclusive. In addition, maximum width Wc of protruding portion 40a may be set to be more than Wa and may be set to be from 10 μm to 50 μm inclusive. As a result, semiconductor laser element 1 can be used as an element that outputs a high-power laser beam exceeding 1 W.

As minimum width Wb of transparent electrode 50 and minimum width Wd of protruding portion 40a are smaller, the higher-order mode in the emitted laser beam can be suppressed, but when minimum width Wb and minimum width Wd are less than a certain value, the basic mode is also suppressed. In addition, when minimum width Wb of transparent electrode 50 and minimum width Wd of protruding portion 40a are more than other certain values, a suppression effect of the higher-order mode is reduced.

Therefore, in the present exemplary embodiment, minimum width Wb of transparent electrode 50 is set to be from ¼ to ¾ inclusive of maximum width Wa, and minimum width Wd of protruding portion 40a is set to be from ¼ to ¾ inclusive of maximum width Wc. As a result, the intensity of the basic mode is maintained, and the laser beam in the suppressed higher-order mode can be emitted.

In the present exemplary embodiment, the thickness of transparent electrode 50 is thicker than the thickness of the waveguide portion, and is more than or equal to 100 nm. For example, the thickness of transparent electrode 50 is 300 nm, the waveguide portion is 100 nm, and distance D is 3 μm. Note that, the thickness of the waveguide portion is a dimension from a bottom surface of p-side cladding layer 42 to the upper surface of the ridge-shaped portion. The thickness of transparent electrode 50 may be more than the thickness of p-side cladding layer 42 at a portion where protruding portion 40a is positioned.

### [Method for Manufacturing Semiconductor Laser Element]

A manufacturing step of semiconductor laser element 1 according to the present exemplary embodiment will be described with reference to FIGS. 3 to 14. FIGS. 3 to 14 are sectional views illustrating manufacturing steps of semiconductor laser element 1.

First, the n-type hexagonal GaN substrate whose main surface is the (0001) surface is prepared as substrate 10. Then, as illustrated in FIG. 3, n-side semiconductor layer 20, light emitting layer 30, and p-side semiconductor layer 40 are sequentially formed on substrate 10 by metalorganic chemical vapor deposition (MOCVD method).

Specifically, the n-side cladding layer made of n-type AlₓGa₁₋ₓN (0<x<1) as n-side semiconductor layer 20 is grown on substrate 10 having a thickness of 400 μm to have a thickness of 3 μm.

Then, n-side light guide layer 31 made of n-type GaN is grown to have a thickness of 0.2 μm. Subsequently, active layer 32 in which the barrier layer made of In_{0.06}Ga_{0.94}N and the quantum well layer made of In_{0.02}Ga_{0.98}N alternately overlap is grown. For example, in active layer 32, the barrier layer and the quantum well layer are alternately stacked over two periods. Further, p-side light guide layer 33 made of p-type GaN is grown to have a thickness of 0.1 μm.

Subsequently, electron barrier layer 41 made of AlGaN is grown to have a thickness of 10 nm. Then, p-side cladding layer 42 made of a strained superlattice formed by repeating a p-type AlGaN layer having a thickness of 1.5 nm and a p-type GaN layer having a thickness of 1.5 nm at a predetermined period is grown to have a thickness of about 0.1 μm. Subsequently, p-side contact layer 43 made of p-type GaN is grown to have a thickness of 0.01 μm.

Note that, for example, trimethylgallium (TMG), trimethylammonium (TMA), and trimethylindium (TMI) are used as organic metal raw materials containing Ga, Al, and In, respectively, during forming of n-side semiconductor layer 20, light emitting layer 30, and p-side semiconductor layer 40. In addition, ammonia (NH₃) is used as a nitrogen raw material.

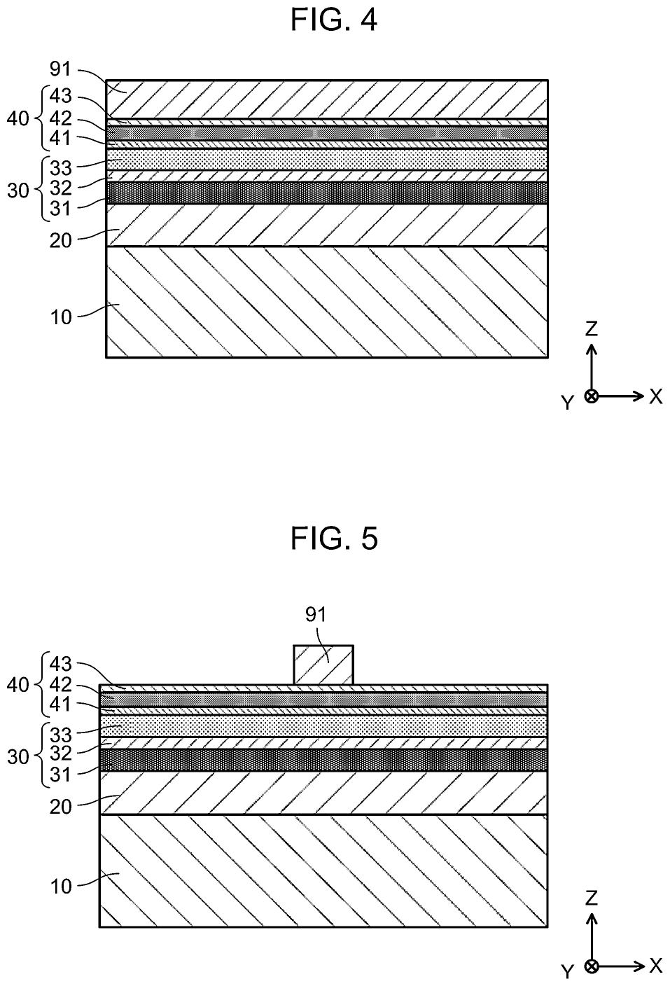

Subsequently, as illustrated in FIG. 4, protective layer 91 is formed on p-side contact layer 43. Specifically, a silicon oxide (SiO₂) layer is formed as protective layer 91 to have a thickness of 300 nm by executing a plasma chemical vapor deposition (CVD) method by using silane (SiH₄).

Note that, the material of protective layer 91 may be a material having selectivity during etching of p-side semiconductor layer 40, such as a dielectric or a metal, and may not necessarily be a silicon oxide (SiO₂) layer. In addition, protective layer 91 may be formed by a method other than plasma CVD, for example, a known forming method such as a thermal CVD method, a sputtering method, a vacuum deposition method, or a pulsed laser deposition method.

Subsequently, as illustrated in FIG. 5, patterning is performed such that protective layer 91 has a predetermined shape. Specifically, a protective film made of a photoresist is deposited on protective layer 91, a part of protective layer 91 is selectively removed by using a photolithography method and an etching method such that protective layer 91 has a predetermined shape, and the protective film is removed. Note that, the predetermined shape is a shape in which a width of protective layer 91 increases or decreases in the Y-axis direction.

A photolithography method using a short wavelength light source, an electron beam lithography method of performing direct writing with an electron beam, a nanoimprint method, or the like may be used as the lithography method. For example, dry etching by reactive ion etching (RIE) using a fluorine-based gas such as CF₄ or wet etching using hydrofluoric acid (HF) diluted to about 10% may be used as the etching method. For example, an organic solvent such as acetone may be used as a solvent for removing the protective film.

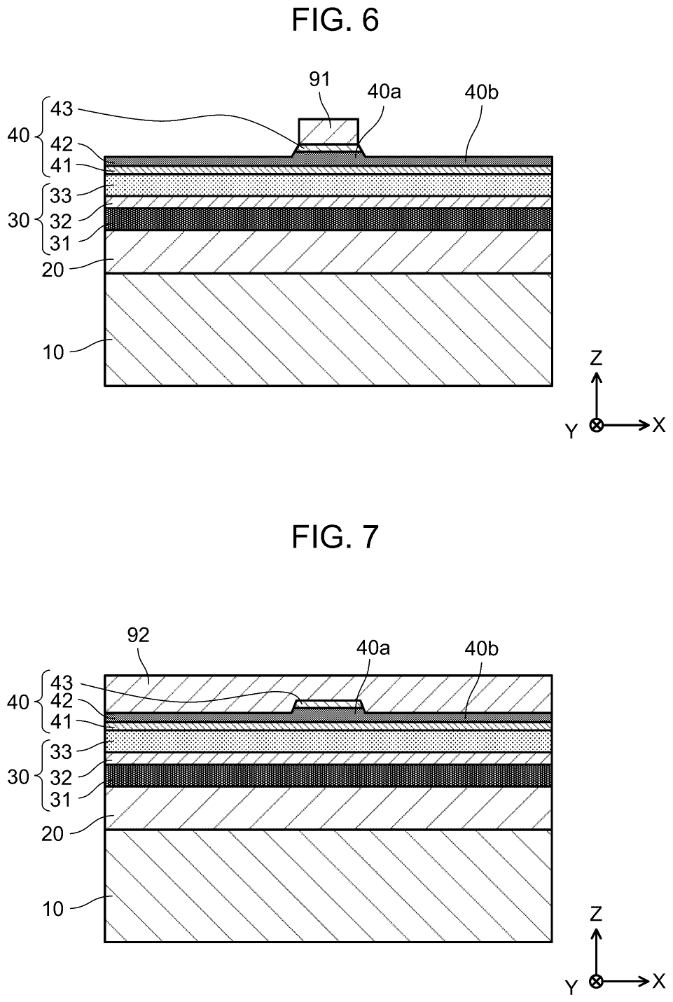

Subsequently, as illustrated in FIG. 6, p-side contact layer 43 and p-side cladding layer 42 are etched by using protective layer 91 as a mask, and thus, the ridge-shaped portion is formed in p-side cladding layer 42. That is, protruding portion 40a and flat portion 40b are formed in p-side semiconductor layer 40. Protruding portion 40a is formed below protective layer 91. In addition, flat portion 40b is formed in a region other than a region below protective layer 91.

Dry etching by a RIE method using a chlorine-based gas such as Cl₂ may be used as the etching of p-side contact layer 43 and p-side cladding layer 42.

Subsequently, protective layer 91 is removed. Protective layer 91 is removed by dry etching or wet etching. Examples of the dry etching include the reactive ion etching (RIE) using the fluorine-based gas such as CF₄. In addition, examples of the wet etching include the hydrofluoric acid (HF) diluted to about 10%.

Subsequently, as illustrated in FIG. 7, protective layer 92 made of a photoresist is formed on p-side contact layer 43 and flat portion 40b.

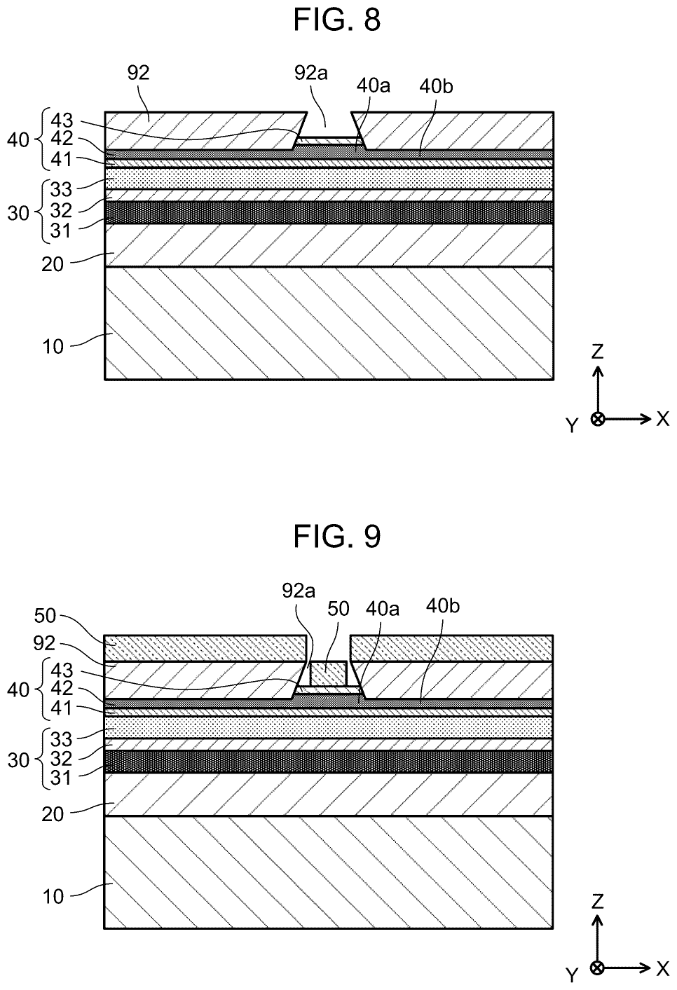

Subsequently, as illustrated in FIG. 8, protective layer 92 covering p-side contact layer 43 is removed by using a photolithography method, and opening portion 92a is formed in protective layer 92. At this time, protective layer 92 is removed such that opening portion 92a has a shape in which a width becomes larger as being closer to p-side contact layer 43 in ZX plan view, that is, an inverse mesa shape. Note that, the width of opening portion 92a increases or decreases along the Y-axis direction in plan view in accordance with an increase or decrease in the width of protruding portion 40a.

Subsequently, as illustrated in FIG. 9, transparent electrode 50 is formed on the entire surface of protective layer 92 and p-side contact layer 43 by using a vacuum deposition method to have a thickness of, for example, 300 nm. Since opening portion 92a has the inverse mesa shape, transparent electrode 50 is not formed in both end regions in the X-axis direction on the upper surface of p-side contact layer 43. That is, transparent electrode 50 is formed such that orthogonal projection 50A of transparent electrode 50 onto light emitting layer 30 is included in orthogonal projection 40A of protruding portion 40a onto light emitting layer 30. In addition, the width of transparent electrode 50 formed on protruding portion 40a increases or decreases along the Y-axis direction to correspond to the increase or decrease in the width of opening portion 92a.

Transparent electrode 50 may be formed by a sputtering method, a pulsed laser deposition method, or the like in addition to the vacuum deposition method. In addition, a transparent conductive oxide material, such as ITO, In₂O₃, or ZnO, which is in ohmic contact with p-side contact layer 43, is formed as the material of transparent electrode 50.

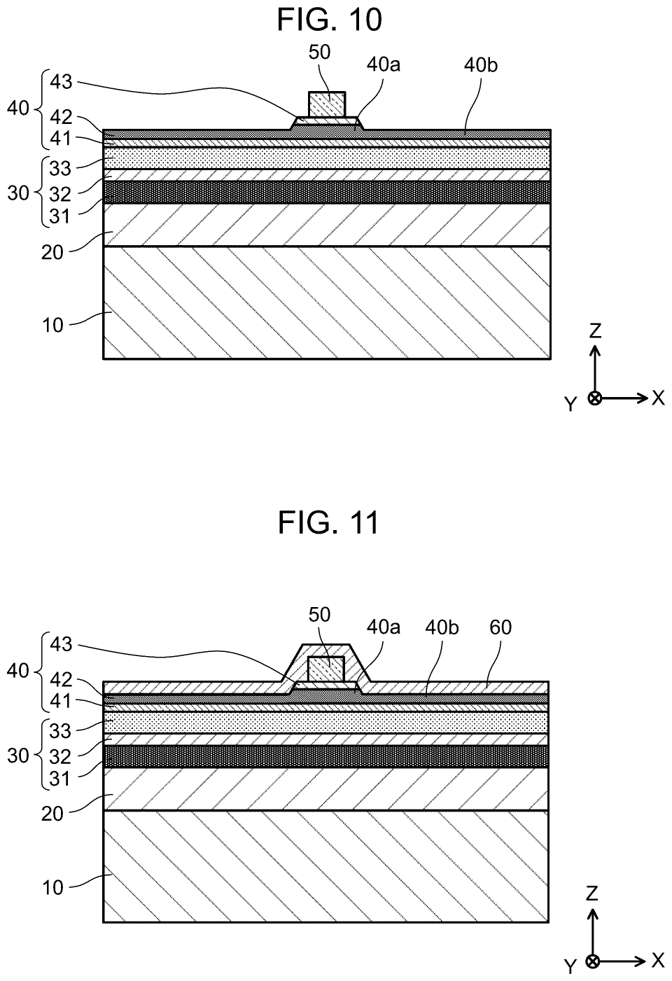

Subsequently, as illustrated in FIG. 10, protective layer 92 is removed by using an organic solvent such as acetone (so-called lift-off method). As a result, transparent electrode 50 on protective layer 92 is removed, and only transparent electrode 50 on protruding portion 40a remains.

Subsequently, as illustrated in FIG. 11, dielectric layer 60 is formed on transparent electrode 50, p-side contact layer 43, and flat portion 40b. Here, as dielectric layer 60, for example, a silicon oxide (SiO₂) layer is formed to have a thickness of 300 nm by a plasma CVD method using silane (SiH₄).

In a step of forming an end surface coating film to be described later, the end surface coating film is usually formed on a portion other than front end surface Cf. That is, at both ends in the Y-axis direction, the end surface coating film is also formed on a front surface of dielectric layer 60 and at a portion aligned with p-side contact layer 43 and flat portion 40b in the Z-axis direction. In addition, in a case where dielectric layer 60 is not formed (that is, in a case where the thickness of dielectric layer 60 is 0), the end surface coating film is also formed on front surfaces of p-side contact layer 43 and flat portion 40b.

Thus, in a case where dielectric layer 60 is extremely thin, a light distribution of the laser beam emitted by light emitting layer 30 overlaps the end surface coating film formed on the front surface of dielectric layer 60. In addition, in a case where dielectric layer 60 is not formed, a light distribution of the laser beam emitted from light emitting layer 30 overlaps the end surface coating film formed on the front surfaces of p-side contact layer 43 and flat portion 40b. In either case, it becomes difficult to confine the laser beam in the waveguide portion, and thus, a loss of the laser beam is generated.

In the present exemplary embodiment, the thickness of dielectric layer 60 is more than or equal to 100 nm. Thus, a distance between the end surface coating film on dielectric layer 60 and light emitting layer 30 can be sufficiently increased. Thus, the influence of the end surface coating film formed on the front surface of dielectric layer 60 is reduced, and the laser beam is easily confined in the waveguide portion.

On the other hand, in a case where the thickness of dielectric layer 60 is large, it becomes difficult to form pad electrode 70. Thus, the thickness of dielectric layer 60 is desirably less than or equal to the thicknesses of the waveguide portion and transparent electrode 50.

In addition, there is a possibility that the side surfaces of protruding portion 40a and flat portion 40b are damaged by etching in the etching step when the ridge-shaped portion is formed in p-side cladding layer 42, and scratches are formed. These scratches may cause a leakage current when semiconductor laser element 1 emits the laser beam. In the present exemplary embodiment, since protruding portion 40a and flat portion 40b are covered with dielectric layer 60, the generation of the leakage current can be reduced.

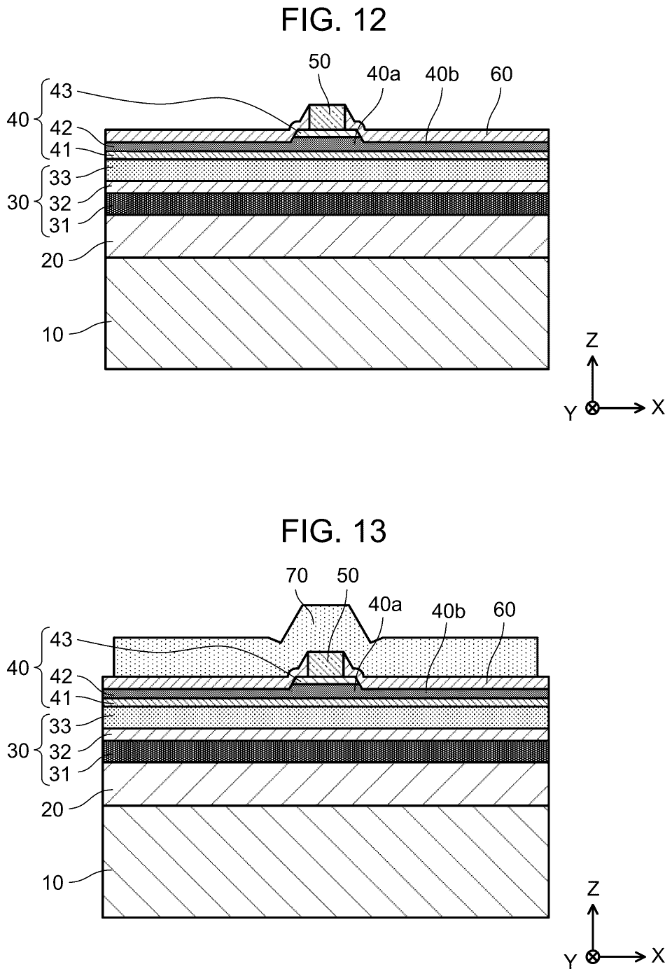

After dielectric layer 60 is formed, as illustrated in FIG. 12, only dielectric layer 60 covering the upper surface of transparent electrode 50 is removed by using a photolithography method and wet etching using hydrofluoric acid to expose the upper surface of transparent electrode 50.

Subsequently, as illustrated in FIG. 13, pad electrode 70 is formed to cover transparent electrode 50 and dielectric layer 60. Specifically, a negative resist is patterned in a peripheral portion of dielectric layer 60 in plan view by a photolithography method or the like. Subsequently, pad electrode 70 including, for example, a Ti layer, a Pt layer, and an Au layer is formed on the entire upper surface of substrate 10 by a vacuum deposition method or the like. Subsequently, pad electrode 70 on the negative resist is removed by a lift-off method. Through the above steps, pad electrode 70 covering transparent electrode 50 and dielectric layer 60 is formed at a position excluding the peripheral portion of dielectric layer 60.

Then, substrate 10 is polished such that the thickness of substrate 10 is about 90 μm.

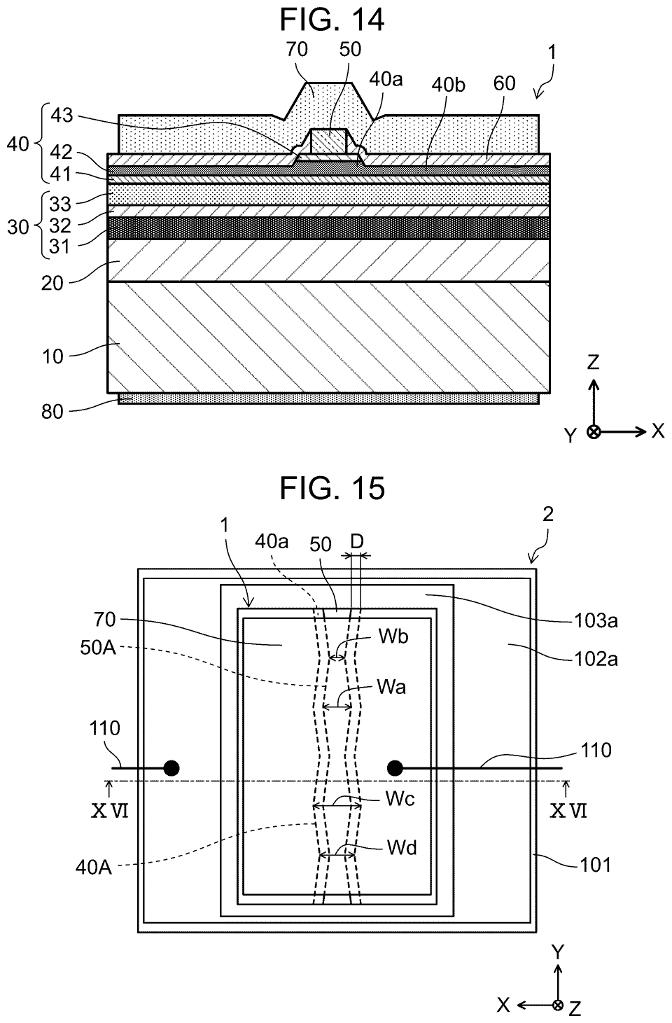

Subsequently, as illustrated in FIG. 14, n-side electrode 80 is formed on the back surface of substrate 10. Specifically, n-side electrode 80 including a Ti layer, a Pt layer, and an Au layer is formed on the back surface of substrate 10 by a vacuum vapor deposition method or the like, and patterning is performed by using a photolithography method and an etching method to form n-side electrode 80 having a predetermined shape.

Subsequently, a length in the Y direction becomes a resonator length size from the substrate, a bar in which a plurality of resonators are aligned is cut out in the X direction, and an end surface coating film is formed on front end surface Cf and rear end surface Cr. Finally, the plurality of resonators aligned in the X direction is diced.

Through the above steps, semiconductor laser element 1 is manufactured.

### [Implementation Form of Semiconductor Laser Element]

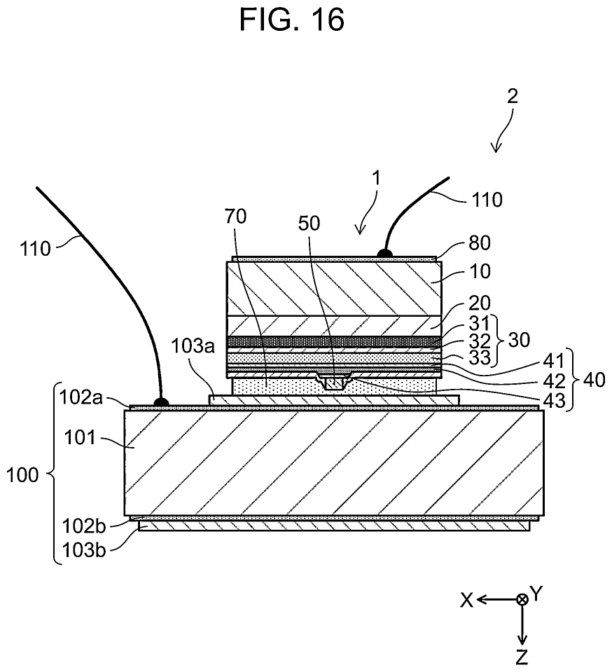

Next, an implementation form of semiconductor laser element 1 will be described with reference to FIGS. 15 and 16. FIG. 15 is a plan view of semiconductor laser device 2 on which semiconductor laser element 1 is implemented. FIG. 16 is a sectional view taken along line XVI-XVI in FIG. 15.

Semiconductor laser device 2 includes semiconductor laser element 1 and submount 100. Semiconductor laser device 2 is formed by implementing semiconductor laser element 1 on submount 100.

Submount 100 includes base 101, first electrode 102a, second electrode 102b, first adhesive layer 103a, and second adhesive layer 103b.

Base 101 functions as a heat sink. Base 101 may be made of a material having thermal conductivity more than or equal to thermal conductivity of semiconductor laser element 1, for example, a ceramic such as aluminum nitride (AlN) or silicon carbide (SIC), a simple metal such as diamond (C), Cu, or Al deposited by CVD, or an alloy such as CuW.

First electrode 102a is disposed on one surface of base 101. In addition, second electrode 102b is disposed on the other surface of base 101. First electrode 102a and second electrode 102b have a stacked structure including, for example, a Ti layer having a thickness of 0.1 μm, a Pt layer having a thickness of 0.2 μm, and an Au layer having a thickness of 0.2 μm.

First adhesive layer 103a is disposed on a front surface of first electrode 102a. Second adhesive layer 103b is disposed on a back surface of second electrode 102b. First adhesive layer 103a and second adhesive layer 103b are, for example, eutectic solder layers made of gold tin alloys containing Au and Sn at contents of 70% and 30%, respectively.

In the present exemplary embodiment, pad electrode 70 of semiconductor laser element 1 is connected to first adhesive layer 103a of submount 100. That is, in the present exemplary embodiment, semiconductor laser element 1 is implemented on submount 100 by so-called junction-down implementation.

Note that, although not illustrated, submount 100 may be implemented on a metal package such as a CAN package, for example, for improving heat dissipation and simplifying handling. In this case, submount 100 is adhered to the metal package via second adhesive layer 103b. In addition, base 101 itself may function as a package. In this case, submount 100 may not include second adhesive layer 103b.

n-side electrode 80 of semiconductor laser element 1 and first electrode 102a of submount 100 are connected to a current supply device via wire 110. As a result, a current can be supplied to semiconductor laser element 1 via wire 110.

### [Structural Parameters]

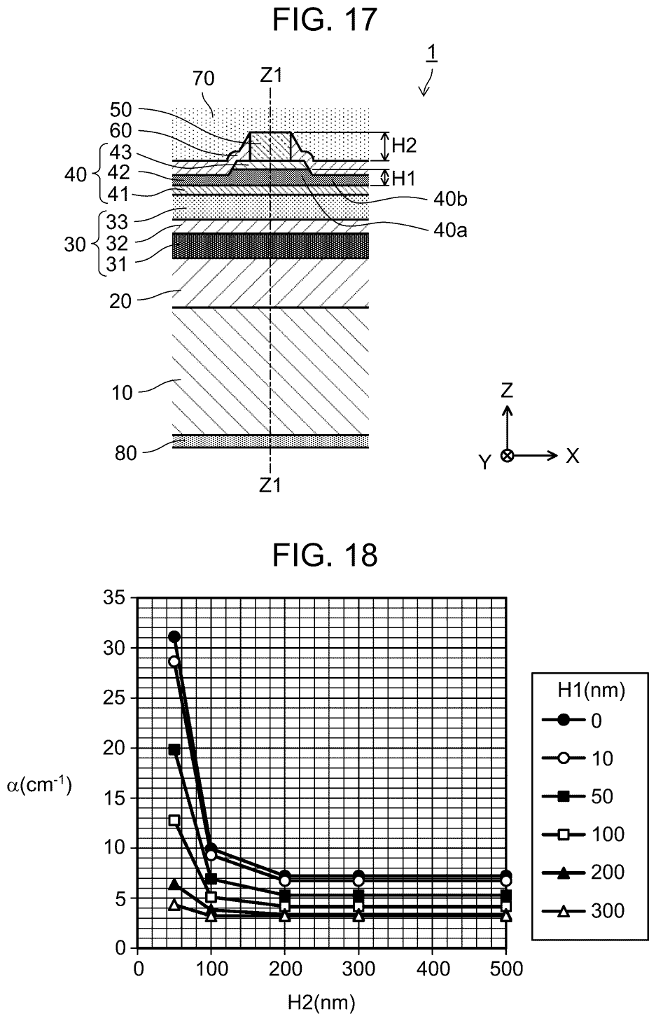

Next, a relationship between structural parameters and laser beam characteristics in semiconductor laser element 1 will be described with reference to FIGS. 17 to 19. The structural parameters mentioned here are the thickness of the waveguide portion and the thickness of transparent electrode 50. The thickness of the waveguide portion coincides with the thickness of p-side cladding layer 42 at the portion where protruding portion 40a is positioned.

### <Loss of Laser Beam>

First, a calculation result regarding the loss of the laser beam will be described with reference to FIGS. 17 and 18. FIG. 17 is a partially enlarged view of FIG. 2. FIG. 18 is a graph representing a calculation result regarding a waveguide loss.

The waveguide loss is an attenuation proportion of energy of the laser beam per unit length of the waveguide portion. Thus, the larger the waveguide loss, the more easily the laser beam is attenuated, and the smaller the waveguide loss, the less easily the laser beam is attenuated.

When the waveguide loss is a, a distance from a predetermined reference position is X, the energy of the laser beam at a position away from the reference position by distance X is I(X), and the energy of the laser beam at the reference position is I₀, a relationship of Expression (1) is established.

I(X)=I₀×exp(−α×X) (1)

Next, a method for calculating waveguide loss α will be described. The inventor has approximated and calculated a three-dimensional structure (that is, ridge structure) of the waveguide portion with a two-dimensional slab waveguide structure by using an equivalent refractive index method.

First, a light distribution and an equivalent refractive index (that is, effective refractive index) of the laser beam in the Z-axis direction were calculated by using a thickness and a refractive index of each layer taken along line Z1-Z1 in FIG. 17. The equivalent refractive index is an average refractive index felt by the laser beam.

Although not described in detail, the inventor calculated the equivalent refractive index by discretizing a two-dimensional scalar wave equation and solving an eigenvalue problem. By expressing the refractive index of each layer by a complex number, waveguide loss α can be calculated based on an imaginary part of the refractive index.

For example, in a case where H1 is calculated to be 100 nm and H2 is calculated to be 300 nm, equivalent refractive index ni and waveguide loss α at line Z1-Z1 in FIG. 17 are ni=2.493 and α=4.1 cm⁻¹, respectively. Equivalent refractive index ni and waveguide loss α change in accordance with H1 and H2.

FIG. 18 illustrates a calculation result of a when H1 and H2 are changed. According to the graph of FIGS. 18, as H1 and H2 are smaller, a is larger.

The reason for this is considered to be that as H1 and H2 are smaller, a distance between light emitting layer 30 and pad electrode 70 becomes shorter, and as a result, the light distribution of the laser beam emitted from light emitting layer 30 becomes wider and overlaps pad electrode 70, and the laser beam is easily absorbed by pad electrode 70.

In order to improve the light characteristics of the laser beam, that is, in order to make it difficult to suppress the basic mode, a is desirably smaller. For example, in a case where the high-power laser beam exceeding 1 W, a needs to be less than or equal to 10 cm⁻¹, and desirably less than or equal to 6 cm⁻¹.

According to the graph of FIG. 18, in a case where H2 is more than or equal to 100 nm, a indicates a relatively small value regardless of the value of H1. In addition, according to the graph of FIG. 18, in a case where H2 is more than or equal to 200 nm, a indicates a substantially certain value as long as the value of H1 is the same.

The reason for this is considered as follows. When H2 is more than or equal to a predetermined value (here, 200 nm), since the light distribution of the laser beam does not overlap with pad electrode 70 positioned above transparent electrode 50, the absorption of the laser beam by pad electrode 70 in this portion is considered to be substantially 0. On the other hand, when the value of H1 is the same, the amount of laser beam absorbed by pad electrode 70 positioned other than above transparent electrode 50 is considered to be a substantially certain value regardless of the thickness of transparent electrode 50. Thus, when H2 is more than or equal to a predetermined value (here, 200 nm), the amount of laser beam absorbed by pad electrode 70 is considered to be substantially a certain value.

According to the graph of FIG. 18, when H1 is more than or equal to 50 nm, a of 6 cm⁻¹ or less can be realized by setting H2 to be more than or equal to a certain value. For example, when H1 is 50 nm, a of 6 cm⁻¹ or less can be realized by setting H2 to be more than or equal to 200 nm. In addition, when H1 is more than or equal to 100 nm, a of 6 cm⁻¹ or less can be realized by setting H2 to be more than or equal to 100 nm.

It is very difficult to control a film thickness of transparent electrode 50 on protruding portion 40a by etching. That is, the thickness of transparent electrode 50 depends on the thickness of the layer of transparent electrode 50 (see FIG. 9) formed by a vacuum vapor deposition method or the like. That is, it is difficult to finely adjust thickness H2 of transparent electrode 50. Thus, an allowable range of H2 is desirably as large as possible.

Based on the graph of FIG. 18, an approximate expression of α near of α=6 cm⁻¹ with H1 and H2 as variables is as represented in Expression (2).

$$α \approx 2.5 \times {10}^{- 5} \times H {1}^{2} - 3.3 \times {10}^{- 2} \times H 1 + 9.7 \times {10}^{3} \times H {2}^{( - 1.9 )} + 6.9 \qquad ( 2 )$$

### <Quality of Laser Beam>

Next, a beam parameter product (BPP) will be described.

The BPP is an index of the beam quality, and the smaller the BPP, the narrower a condensing range of the laser beam. That is, the smaller the BPP, the better the beam quality.

The inventor calculated the BPP of semiconductor laser element 1 when D and H1 were changed on the condition that maximum width Wc of protruding portion 40a was 16 μm, minimum width Wd was 8 μm, and H2 was 200 nm.

Next, a method for calculating the BPP will be described. The BPP can be calculated based on the width of the light distribution of the laser beam at front end surface Cf of the waveguide portion and a divergence angle of the laser beam emitted from front end surface Cf.

The inventor has calculated propagation characteristics of the basic mode and the higher-order mode by using a beam propagation method. Specifically, the basic mode and the higher-order mode are incident from one end (incident end) of the waveguide portion in the Y-axis direction, and the propagation characteristics of each mode in the Y-axis direction are calculated. Then, calculation was sequentially performed up to the other end (output end) of the waveguide portion, and the light distribution at the other end (output end) was obtained. Note that, the other end corresponds to front end surface Cf.

Next, the obtained light distribution was Fourier-transformed to calculate a radiation pattern. Further, the BPP was calculated by dividing a product of the width of the energy of the light distribution and the divergence angle based on the radiation pattern by 4. Note that, an energy width including 95% of the entire light distribution was used as the width of the energy of the light distribution.

For example, in a case where H1 is 100 nm, H2 is 200 nm, and D is 2 μm, the energy width of the light distribution is 9.5 μm, the divergence angle of the radiation pattern is 10.0°, and the BPP is determined to be 0.41 mm·mrad.

Note that, the following three effects can be considered as effects that influences the value of the BPP.

### (1) Suppression Effect by Increase and Decrease in Width of Protruding Portion 40a

Since the width of protruding portion 40a increases or decreases in the Y-axis direction, the higher-order mode is scattered, and as a result, the higher-order mode is suppressed.

### (2) Suppression Effect by Increase or Decrease in Width of Transparent Electrode 50

A refractive index of transparent electrode 50 is different from a refractive index in the waveguide portion. When transparent electrode 50 is disposed on protruding portion 40a (that is, on the waveguide portion) and a peripheral portion of the light distribution of the laser beam overlaps transparent electrode 50, the higher-order mode is suppressed by transparent electrode 50. In addition, since the width of transparent electrode 50 increases or decreases in the Y-axis direction, when the peripheral portion of the light distribution of the laser beam overlaps transparent electrode 50, the higher-order mode is scattered, and as a result, the higher-order mode is further suppressed.

### (3) Suppression Effect by Loss Region

When a current is supplied to semiconductor laser element 1, the current flows in a portion of the waveguide portion below transparent electrode 50. On the other hand, a current does not flow in regions (hereinafter, referred to as “loss regions”) other than the portion of the waveguide portion below transparent electrode 50. Thus, the higher-order mode is scattered by the loss regions positioned on both sides of the waveguide portion in the X-axis direction, and is consequently suppressed.

Note that, the effect of (1) occurs regardless of the values of H1 and D.

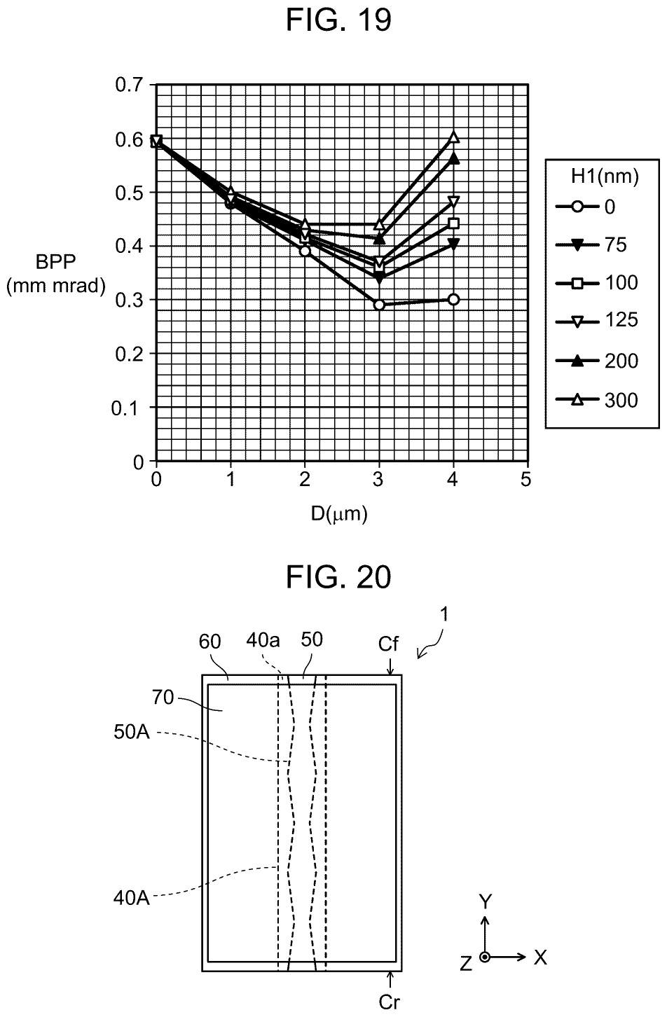

FIG. 19 is a graph representing a calculation result regarding the BPP. FIG. 19 illustrates that the BPP decreases as D increases in a range where D is from 0 μm to 3 μm inclusive. This is considered to be because the higher-order mode is suppressed by the effects of (1) to (3) described above.

For example, in a case where H1 is 300 nm, since the laser beam is sufficiently away from transparent electrode 50, the effect of (2) is reduced. That is, in a case where H1 is 300 nm, it is considered that the effect of (3) mainly contributes to the reduction of the BPP.

The effect of (3) increases as the loss region increases in a range where D is more than 0 and up to 3 μm. In a case where H1 is less than 300 nm, since the light distribution of the laser beam overlaps transparent electrode 50, the effect of (2) is obtained.

The reason why the BPP decreases as H1 decreases is that since a distance between transparent electrode 50 and light emitting layer 30 decreases as H1 decreases, the light distribution of the laser beam overlaps transparent electrode 50 in a wide range, and the effect of (2) increases.

The reason why the BPP represents a relatively large value when D is 4 μm is considered to be that minimum width Wb of transparent electrode 50 becomes 0, a loss region is generated below this portion, and the basic mode is also suppressed.

Note that, the BPP hardly changed even though H2 was changed.

In summary, the loss region in the waveguide portion increases by increasing D, and the effect of (3) increases. In addition, the effect of (2) is increased by increasing or decreasing the width of transparent electrode 50. As a result, the BPP is reduced.

Based on the calculation result illustrated in FIG. 19, the approximate expression of the BPP in a range where the BPP is less than 0.5 mm·mrad is as represented in Expression (3).

$$BPP \approx - 5.6 \times {10}^{- 6} \times H {1}^{2} + 1.6 \times {10}^{- 3} \times H 1 + 9.6 \times {10}^{- 3} \times {D}^{2} - 0.073 \times D + 0.44 \qquad ( 3 )$$

According to FIG. 19, in a case where D was 0 μm, the BPP was 0.59 mm·mrad regardless of the value of H1. The reference value (0.5 mm·mrad) of the BPP that defines an application range of the above Expression (3) is less than 0.59 mm·mrad by about 15%. It can be said that the change from 0.59 mm·mrad to 0.5 mm·mrad significantly improves the beam quality even in consideration of manufacturing variations of semiconductor laser element 1.

A combination of H1 and D that can achieve a BPP less than 0.5 mm·mrad can be obtained by using Expression (3).

As described above, according to the calculation results of the waveguide loss and the BPP, the BPP is improved but a is increased by decreasing H1. In other words, the beam quality is improved by decreasing H1, but the laser beam is easily attenuated including the basic mode.

For example, in a case where H2 is 200 nm, H1 is 100 nm (a value of 50 nm or more) and D is 3 μm, and thus, a (high power) of 6 cm⁻¹ or less and BPP (high beam quality) of about 0.36 mm·mrad can be realized. Note that, 0.36 mm·mrad is about 39% less than 0.59 mm·mrad which is BPP when D is 0.

As described above, semiconductor laser element 1 according to the present exemplary embodiment includes light emitting layer 30, p-side semiconductor layer 40, and transparent electrode 50 that are stacked to be aligned in the first direction. p-side semiconductor layer 40 is disposed between light emitting layer 30 and transparent electrode 50, and has flat portion 40b and protruding portion 40a protruding from flat portion 40b toward transparent electrode 50 and extending in the second direction. Transparent electrode 50 extends in the second direction, and is disposed such that orthogonal projection 50A of transparent electrode 50 onto light emitting layer 30 is included in orthogonal projection 40A of the protruding portion onto light emitting layer 30.

As a result, since the effect of (3) described above can be obtained, the BPP of the laser beam emitted from semiconductor laser element 1 can be reduced. In addition, it is possible to suppress the higher-order mode while setting the width of protruding portion 40a to be relatively wide. That is, the higher-order mode can be suppressed without suppressing the basic mode. Thus, the proportion of the higher-order modes in the laser beam can be reduced. Accordingly, semiconductor laser element 1 that emits the laser beam with high beam quality can be realized.

Further, in semiconductor laser element 1 according to the present exemplary embodiment, at least one of transparent electrode 50 and protruding portion 40a has a first portion and a second portion adjacent to the first portion in the second direction, the first portion having a width which increases along the second direction, the second portion having a width which decreases along the second direction.

Thus, since the effects of (1) and (2) described above can be easily obtained, the higher-order mode can be further suppressed.

More specifically, at least one of transparent electrode 50 and protruding portion 40a has a first portion and a second portion adjacent to the first portion in the second direction, the first portion having a width which periodically increases along the second direction, the second portion having a width which periodically decreases along the second direction.

In semiconductor laser element 1 according to the present exemplary embodiment, dielectric layer 60 covers the side surfaces of transparent electrode 50 and protruding portion 40a, and is made of a low refractive index material having a refractive index lower than a refractive index of the material constituting transparent electrode 50 and the material constituting protruding portion 40a.

Thus, even though the end surface coating film is formed on the front surface of dielectric layer 60 at the portion aligned with p-side contact layer 43 and flat portion 40b in the Z-axis direction, the distance between the end surface coating film and light emitting layer 30 can be sufficiently increased. Thus, the laser beam is easily confined in the waveguide portion.

In addition, it is possible to make it difficult to generate the leakage current due to the scratches on the side surfaces of protruding portion 40a and flat portion 40b.

In semiconductor laser element 1 according to the present exemplary embodiment, dielectric layer 60 is made of SiO₂. As a result, the refractive index of dielectric layer 60 can be set to be lower than the refractive indexes of transparent electrode 50 and the waveguide portion.

In semiconductor laser element 1 according to the present exemplary embodiment, transparent electrode 50 is thicker than the waveguide portion. According to the calculation result illustrated in FIG. 18, the larger thickness H2 of transparent electrode 50, the smaller waveguide loss α. Thus, a power value of the emitted laser beam can be set to be less likely to be reduced by forming transparent electrode 50 to be relatively thick, for example, to be thicker than the waveguide portion.

In semiconductor laser element 1 according to the present exemplary embodiment, the thickness of transparent electrode 50 is more than or equal to 100 nm. For example, the thickness of transparent electrode 50 is set to 300 nm, the thickness of the waveguide portion is set to 100 nm, and distance D is set to 3 μm. As a result, the beam quality can be improved while maintaining an optical power.

### (Modification 1)

Hereinafter, differences from the exemplary embodiment will be mainly described for semiconductor laser element 1 according to Modification 1 with reference to FIG. 20. FIG. 20 is a plan view of semiconductor laser element 1 according to Modification 1.

As in the exemplary embodiment, in Modification 1, transparent electrode 50 has a shape whose width increases or decreases along the Y-axis direction (second direction). On the other hand, protruding portion 40a has a shape having a constant width along the Y-axis direction.

According to Modification 1, since the effects of (2) and (3) described above can be obtained, the BPP of the laser beam emitted from semiconductor laser element 1 can be reduced. In addition, it is possible to suppress the higher-order mode while setting the width of protruding portion 40a to be relatively wide. Accordingly, semiconductor laser element 1 that emits the laser beam with high beam quality can be realized.

### (Modification 2)

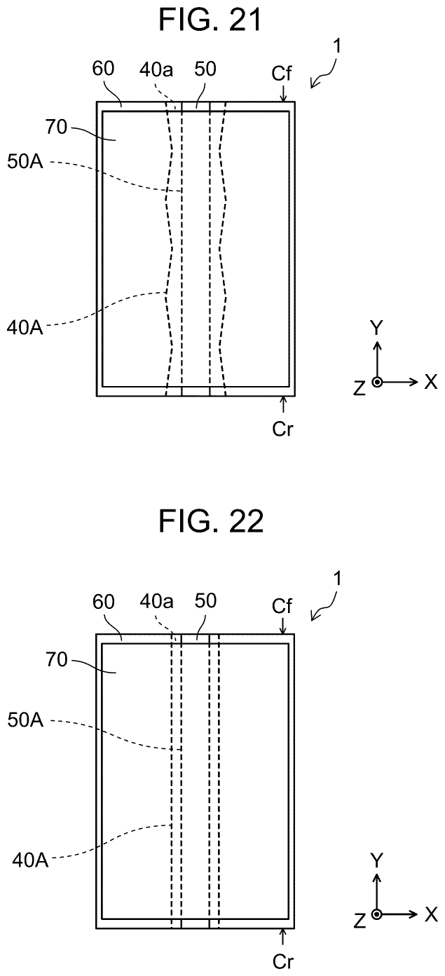

Hereinafter, differences from the exemplary embodiment will be mainly described for semiconductor laser element 1 according to Modification 2 with reference to FIG. 21. FIG. 21 is a plan view of semiconductor laser element 1 according to Modification 2.

As in the exemplary embodiment, in Modification 2, protruding portion 40a has a shape whose width increases or decreases along the Y-axis direction (second direction). On the other hand, transparent electrode 50 has a shape having a constant width along the Y-axis direction.

According to Modification 2, at least the effects of (1) and (3) can be obtained. Thus, the BPP of the laser beam emitted from semiconductor laser element 1 can be reduced. In addition, it is possible to suppress the higher-order mode while setting the width of protruding portion 40a to be relatively wide. Accordingly, semiconductor laser element 1 that emits the laser beam with high beam quality can be realized.

### (Modification 3)

Hereinafter, differences from the exemplary embodiment will be mainly described for semiconductor laser element 1 according to Modification 3 with reference to FIG. 22. FIG. 22 is a plan view of semiconductor laser element 1 according to Modification 3.

In Modification 3, protruding portion 40a and transparent electrode 50 have a shape having a constant width along the Y-axis direction.

According to Modification 3, at least the effect of (3) can be obtained. Thus, the BPP of the laser beam emitted from semiconductor laser element 1 can be reduced. In addition, it is possible to suppress the higher-order mode while ensuring the relatively wide width of protruding portion 40a. Accordingly, semiconductor laser element 1 that emits the laser beam with high beam quality can be realized.

### (Other Modifications)

In the above-described exemplary embodiment and modifications, it has been described that semiconductor laser element 1 is a nitride semiconductor laser element. However, semiconductor laser element 1 may be, for example, a gallium arsenide semiconductor laser element.

In addition, protruding portion 40a may have a shape whose width increases or decreases in a curved shape along the Y-axis direction. In addition, protruding portion 40a may have a portion having a constant width along the Y-axis direction and a portion having a width that increases or decreases along the Y-axis direction.

Similarly, transparent electrode 50 may have a shape in which the width increases or decreases in a curved shape along the Y-axis direction. In addition, transparent electrode 50 may have a portion having a constant width along the Y-axis direction and a portion having a width that increases or decreases along the Y-axis direction.

The present disclosure also includes a mode obtained by making various modifications conceivable by those skilled in the art to each of the exemplary embodiments and modifications, and a mode obtained by combining any components and any functions in each of the exemplary embodiments without departing from the gist of the present disclosure.

According to the present disclosure, it is possible to provide the semiconductor laser element capable of emitting the laser beam with high beam quality.

### INDUSTRIAL APPLICABILITY

The present disclosure is suitable for the semiconductor laser element that is required to emit the laser beam with high power and high beam quality.

### REFERENCE MARKS IN THE DRAWINGS

1: semiconductor laser element
2: semiconductor laser device
10: substrate
20: n-side semiconductor layer
30: light emitting layer
31: n-side light guide layer
32: active layer
33: p-side light guide layer
40: p-side semiconductor layer
40a: protruding portion
40b: flat portion
41: electron barrier layer
42: p-side cladding layer
43: p-side contact layer
50: transparent electrode
60: dielectric layer
80: n-side electrode
Cf: front end surface
Cr: rear end surface

1. A semiconductor laser element comprising:
a light emitting layer;
a transparent electrode; and
a p-side semiconductor layer disposed between the light emitting layer and the transparent electrode in a first direction,
wherein the p-side semiconductor layer includes a flat portion and a protruding portion protruding from the flat portion toward the transparent electrode, the protruding portion extending in a second direction orthogonal to the first direction,
the transparent electrode extends in the second direction, and
orthogonal projection of the transparent electrode onto the light emitting layer is included in orthogonal projection of the protruding portion onto the light emitting layer.

2. The semiconductor laser element according to claim 1,
wherein at least one of the transparent electrode and the protruding portion has a first portion and a second portion adjacent to the first portion in the second direction, the first portion having a width which increases along the second direction, the second portion having a width which decreases along the second direction.

3. The semiconductor laser element according to claim 1,
wherein each of the transparent electrode and the protruding portion has a first portion and a second portion adjacent to the first portion in the second direction, the first portion having a width which increases along the second direction, the second portion having a width which decreases along the second direction.

4. The semiconductor laser element according to claim 1,
wherein at least one of the transparent electrode and the protruding portion has a first portion and a second portion adjacent to the first portion in the second direction, the first portion having a width which periodically increases along the second direction, the second portion having a width which periodically decreases along the second direction.

5. The semiconductor laser element according to claim 1, further comprising:
a dielectric layer that covers side surfaces of the transparent electrode and the protruding portion, the dielectric layer being made of a low refractive index material having a refractive index lower than a refractive index of a material constituting the transparent electrode and a material constituting the protruding portion.

6. The semiconductor laser element according to claim 5,
wherein the low refractive index material is SiO₂.

7. The semiconductor laser element according to claim 1,
wherein the p-side semiconductor layer includes a p-side cladding layer, and
a thickness of the transparent electrode is more than a thickness of the p-side cladding layer in a portion where the protruding portion is positioned.

8. The semiconductor laser element according to claim 1,
wherein a thickness of the transparent electrode is more than or equal to 100 nm.

9. The semiconductor laser element according to claim 1,
wherein the protruding portion has a width in a third direction orthogonal to the first direction and the second direction,
the transparent electrode has a width in the third direction, and
a width of the transparent electrode is less than a width of the protruding portion at any position in the second direction.
